(19) United States
(12) Patent Application Publication
(10) Pub. No.: US 2006/0099348 A1
(43) Pub. Date: May 11, 2006

(54) Deposition method

(75) Inventors: Masaki Narushima, Nirasaki-Shi (JP); Koumei Matsuzawa, Uodu-Shi (JP); Takayuki Komiya, Nirasaki-Shi (JP); Eiichi Kondoh, Kai-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Minato-Ku (JP); EIICHI KONDOH, Kai-Shi (JP)

(21) Appl. No.: 11/249,390

(22) Filed: Oct. 14, 2005

(30) Foreign Application Priority Data
Oct. 19, 2004 (JP) 2004-304537

(51) Int. Cl. C23C 16/00

(52) U.S. Cl. 427/444

(57) ABSTRACT

A deposition method for depositing on a substrate includes the step of: using a process medium made by adding a precursor to a medium in a supercritical state. The precursor is added to the medium in the supercritical state where the precursor is dissolved in an organic solvent.

### BACKGROUND OF THE INVENTION

1. Field of the Invention

The present invention generally relates to deposition methods, and more specifically to a deposition method using a medium in a supercritical state.

2. Description of the Related Art

Recently and continuing, as performance and function of semiconductor devices are becoming high, high integration of the semiconductor devices is being promoted and it is extremely desired that the semiconductor devices have fine structures.

A technology for a wiring rule equal to or less than 0.10 μm has been developing. In addition, copper (Cu) is used as a wiring material for the semiconductor device. This is because Cu has a low resistance value and little influence of wiring delay is given thereto.

Because of this, the combination of a Cu deposition technology and a fine wiring technology is important for the recent fine multi-layer wiring technology.

A sputtering method, chemical vapor deposition (CVD) method, plating method, or the like is generally known as a deposition method for Cu. However, each method has a limitation in coverage on the fine wiring and therefore it is extremely difficult to efficiently deposit on a fine pattern having a high aspect ratio and a length less than 0.1 μm, or form Cu wiring by, for example, deposition of Cu.

Because of this, a method for depositing on the fine pattern using a medium in a supercritical state is suggested as a method for efficiently depositing on the fine pattern.

In a case where the material in the supercritical state is used as a medium for dissolving a precursor chemical compound (hereinafter “precursor”) for deposition, since the material has a density and dissolution close to liquid, it is possible to keep the dissolution of a precursor high, as compared to a gas medium.

Furthermore, by using a diffusion coefficient close to gas, it is possible to introduce the precursor to the substrate more efficiently than the liquid medium. Therefore, in a deposition wherein a process medium made by dissolving the precursor in the medium in the supercritical state is used, the deposition rate can be made high and a good coverage of the fine pattern by the deposition can be obtained.

A precursor for depositing Cu is dissolved by using CO₂ in a supercritical state so that Cu is deposited on the fine pattern. See “Deposition of Conformal Copper and Nickel Films from Supercritical Carbon Dioxide” SCIENCE Vol. 294, Oct. 5, 2001.

In this case, in the above-mentioned medium in the supercritical state of CO₂, Cu deposition precursor, namely a precursor chemical compound including Cu, has high dissolution while it has a low viscosity and high diffusion. Therefore, it is possible to deposit Cu on the above-mentioned fine pattern having a high aspect ratio.

If necessary, the medium in the supercritical state may be used by adding a reducing agent of the precursor such as H₂ gas.

However, in a case of the deposition method using the above-discussed medium in the supercritical state, there is a problem in that a material supplied on the substrate such as the precursor or a reducing agent of the precursor cannot be stably supplied.

For example, for the purpose of supplying the precursor on the substrate, a step for adding the precursor to the medium in the supercritical state is necessary in order to dissolve the precursor in the medium in the supercritical state. It is difficult to add the precursor to the medium in the supercritical state continuously and reproducibly at a stable density. Particularly, if the precursor is solid at normal temperature, it is difficult to dissolve the precursor in the medium in the supercritical state at the stable density.

In addition, in a case where a continuous process is performed on plural substrates, it is difficult to continuously supply a proper amount of the precursor on the substrate.

Furthermore, for example, in a case where a reducing agent reducing the precursor is supplied on the substrate, it is necessary to add the reducing agent to the medium in the supercritical state. It is difficult to supply the reducing agent continuously and reproducibly so that a stable mixing ratio is obtained.

In addition, since H₂ gas is a combustible, highly explosive gas, there may be danger in taking in a large amount of H₂ gas. Furthermore, it is also difficult to directly mix high pressure CO₂ and low pressure H₂.

### SUMMARY OF THE INVENTION

Accordingly, it is a general object of the present invention to provide a novel and useful deposition method.

Another object of the present invention is to provide a deposition method using a medium in a supercritical state whereby a supplied material is stably supplied on a substrate.

More specifically, a first object of the present invention is to provide a deposition method using a medium in a supercritical state whereby a precursor is stably supplied on a substrate.

A second object of the present invention is to provide a deposition method using a medium in a supercritical state whereby a reducing agent reducing a precursor dissolved in the medium in the supercritical state is stably supplied on a substrate.

The above objects of the present invention are achieved by a deposition method for depositing on a substrate, including the step of:

using a process medium made by adding a precursor to a medium in a supercritical state;

wherein the precursor is added to the medium in the supercritical state where the precursor is dissolved in an organic solvent.

The above objects of the present invention are achieved by a deposition method wherein a precursor, a medium in a supercritical state dissolving the precursor, and a reducing agent reducing the precursor are supplied on a substrate held in a process vessel so that deposition is implemented, the deposition method including the steps of:

a first step of supplying the reducing agent to a mixing vessel mixing the reducing agent and a dilution agent of the reducing agent;

a second step of supplying the dilution agent to the mixing vessel so as to dilute the reducing agent and form a mixed medium;

a third step of compressing the mixed medium; and

a fourth step of supplying the mixed medium into the process vessel.

The above objects of the present invention are achieved by a deposition method wherein a precursor, a medium in a supercritical state dissolving the precursor, and a reducing agent reducing the precursor are supplied on a substrate held in a process vessel so that deposition is implemented; and the precursor is added to the medium in the supercritical state where the precursor is dissolved in an organic solvent; the deposition method including:

a first step of supplying the reducing agent to a mixing vessel mixing the reducing agent and a dilution agent of the reducing agent;

a second step of supplying the dilution agent to the mixing vessel so as to dilute the reducing agent and form a mixed medium;

a third step of compressing the mixed medium; and

a fourth step of supplying the mixed medium into the process vessel.

The above objects of the present invention are achieved by a recording medium wherein a program making a computer implement a deposition method is recorded, the deposition method being wherein a precursor, a medium in a supercritical state dissolving the precursor, and a reducing agent reducing the precursor are supplied on a substrate held in a process vessel so that deposition is implemented, the deposition method including:

a first step of supplying the reducing agent to a mixing vessel mixing the reducing agent and a dilution agent of the reducing agent;

a second step of supplying the dilution agent to the mixing vessel so as to dilute the reducing agent and form a mixed medium;

a third step of compressing the mixed medium; and

a fourth step of supplying the mixed medium into the process vessel.

The above objects of the present invention are achieved by a recording medium wherein a program making a computer implement a deposition method is recorded, the deposition method being wherein a precursor, a medium in a supercritical state dissolving the precursor, and a reducing agent reducing the precursor are supplied on a substrate held in a process vessel so that deposition is implemented; and the precursor is added to the medium in the supercritical state where the precursor is dissolved in an organic solvent; the deposition method including:

a first step of supplying the reducing agent to a mixing vessel mixing the reducing agent and a dilution agent of the reducing agent;

a second step of supplying the dilution agent to the mixing vessel so as to dilute the reducing agent and form a mixed agent;

a third step of compressing the mixed medium; and

a fourth step of supplying the mixed medium into the process vessel.

According to the above-mentioned invention, it is possible to stably supply a material on a substrate.

Other objects, features, and advantages of the present invention will become more apparent from the following detailed description when read in conjunction with the accompanying drawings.

### BRIEF DESCRIPTION OF THE DRAWINGS

FIG. 1 is a schematic view of an example of a deposition apparatus used for a deposition method of a first embodiment of the present invention;

FIG. 2 is a flowchart showing the deposition method according to the first embodiment of the present invention;

FIG. 3 is a schematic view of an example of a deposition apparatus used for a deposition method of a second embodiment of the present invention;

FIG. 4 is a schematic view showing details of steps for supplying a mixed medium by using a mixing vessel shown in FIG. 3;

FIG. 5 is a first view showing manufacturing steps of a semiconductor device using the deposition method according to the first and second embodiments of the present invention; and

FIG. 6 is a second view showing manufacturing steps of the semiconductor device using the deposition method according to the first and second embodiments of the present invention.

### DETAILED DESCRIPTION OF THE PREFERED EMBODIMENTS

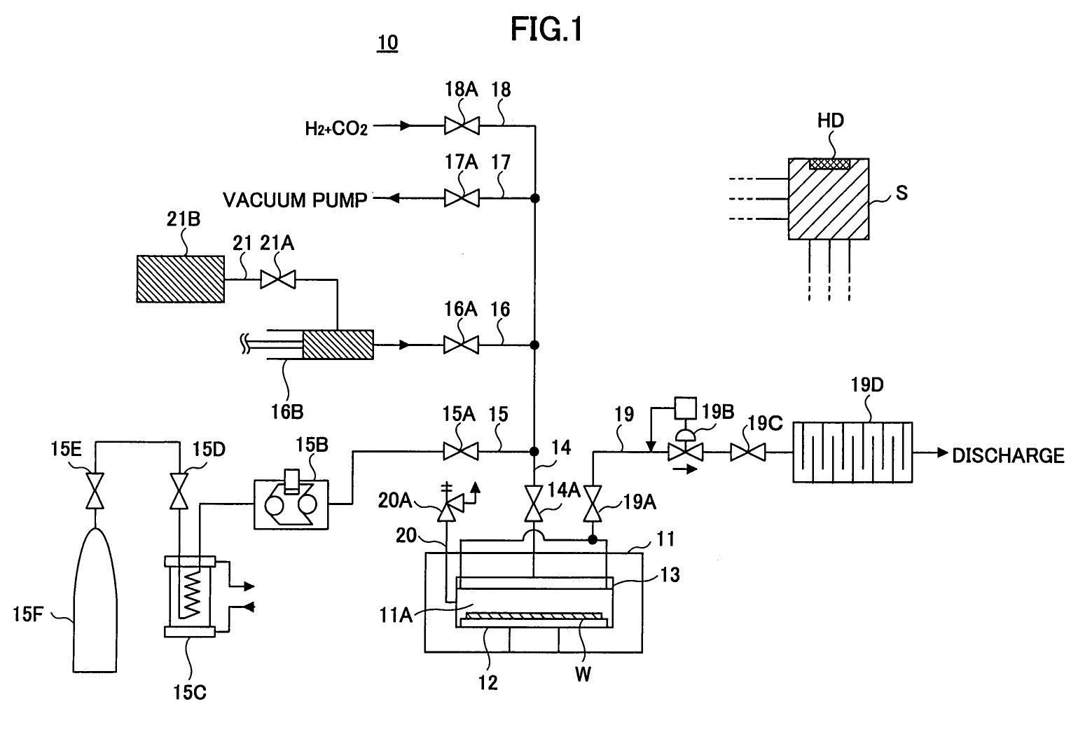

A description will now be given, with reference to FIG. 1 through FIG. 6, of embodiments of the present invention.

### First Embodiment

In a deposition method of this embodiment, deposition is performed on a substrate by using a medium (hereinafter “process medium”) wherein a precursor is dissolved in the medium in a supercritical state. In this case, the precursor is added to the medium in the supercritical state while the precursor is dissolved in an organic solvent.

Conventionally, it is difficult to continuously and stably add to and dissolve the precursor in the medium in the supercritical state. Particularly, it is difficult to stably dissolve a precursor which is solid at normal temperature in the medium in the supercritical state so that a continuous deposition is performed on plural substrates. In this embodiment, the precursor is dissolved in the organic solvent and the organic solvent where the precursor is dissolved is added to the medium in the supercritical state.

For example, the medium in the supercritical state is supplied to the substrate and the organic solvent in which the precursor is dissolved is added to the medium in the supercritical state. The process medium in a state where the precursor is dissolved in the medium in the supercritical state is formed on the substrate.

Because of this, in the deposition method in this embodiment, the precursor can be stably supplied to the substrate so that process efficiency can be improved.

FIG. 1 is a schematic view of an example of a deposition apparatus 10 used for a deposition method of a first embodiment of the present invention.

Referring to FIG. 1, the deposition apparatus 10 includes a process vessel 11. A process space 11A is formed inside of the deposition apparatus 10. A support stand 12 is provided inside of the process vessel 11 so as to support a substrate W. A heating part (not shown in FIG. 1) such as a heater is provided in the support table 12 so that the substrate W supported on the support table can be heated.

A supply part 13 is provided at a side facing the support table 12 in the process vessel 11. The supply part 13 has a showerhead structure where plural supply holes for supplying a medium in the supercritical state or the organic solvent where the precursor is dissolved into the process space 11A are formed. A supply line 14 having a valve 14A is connected to the supply part 13.

The medium in the supercritical state or the organic solvent where the precursor is dissolved is supplied from the supply line 14 into the process space 11A via the supply part 13. A line 15 having a valve 15A, a line 16 having a valve 16A, and a line 18 having a valve 18A are connected to the supply line 14. The line 15 supplies the medium in the supercritical state to the supply line 14. The line 16 supplies the precursor to the supply line 14. The line 18 supplies gas necessary for a deposition process such as a reducing agent for reducing the precursor to the supply line 14.

A line 17 having a valve 17A is connected to the supply line 14. A vacuum pump (not shown in FIG. 1) for evacuating the process space 11A or the supply line 14, if necessary, is connected to the line 17.

A cylinder bottle 15F is connected to the line 15 via a pressing pump 15B, a cooling apparatus 15C, and valves 15D and 15E. For example, an original medium for forming the medium in the supercritical state, such as CO₂, is provided inside the cylinder bottle 15F.

CO₂ supplied from the cylinder bottle 15F is cooled by the cooling apparatus 15C, compressed by the pressing pump 15B so as to have a designated pressure and temperature, and supplied to the process space 11A as the medium in the supercritical state. For example, in the case of CO₂, the critical point (which is the point for the start of the supercritical state) is a temperature 31.0° C. and a pressure 7.38 MPa. When the temperature and the pressure are higher than the critical point, CO₂ assumes the supercritical state.

A discharge line 19 having valves 19A and 19C and a trap 19D is connected to the process vessel 11. The discharge line 19 discharges a process medium supplied to the process space 11A or the medium in the supercritical state. For example, the discharge line 19 catches the precursor dissolved in the process medium by the trap 19D and discharges the process medium to the outside of the process space.

A pressure control valve 19B is installed in the discharge line 19 so that the processed medium supplied to the process space 11A or the medium in the supercritical state can be discharged while the pressure of the discharge line 19 is controlled to have a designated value. An explosion-proof line 20 and an explosion-proof valve 20A are provided in the process space 11A so that the process space 11A can be prevented from having a pressure higher than the process vessel 11 can endure.

In the deposition apparatus 10 of this embodiment, a supply vessel 16B is connected to the line 16 so as to supply the precursor on the substrate in the process vessel 11. The supply vessel 16B includes, for example, a cylinder pump. An organic solvent (hereinafter “addition organic solvent”) where the precursor is dissolved is held in the supply vessel 16B.

A solvent tank 21B is connected to the supply vessel 16B via the line 21 having the valve 21A. The addition organic solvent held in the solvent tank 21B is supplied to the supply vessel 16B. A sufficient amount of the addition organic solvent having a designated concentration is formed in advance and held in the tank 21B for deposition on plural substrates.

The valve 16A is opened and the addition organic solvent is compressed by the cylinder pump, if necessary, so that the addition organic solvent is supplied from the line 14 to the process space 11A via the supply part 13.

The supplied addition organic solvent is added to the medium in the supercritical state supplied to the process space 11A, so that the precursor is in a state where it is dissolved in the medium in the supercritical state, and the process medium is formed and supplied on the substrate.

Conventionally, in a case where the precursor is directly dissolved in the medium in the supercritical state, it is difficult to continuously and stably supply the medium in the supercritical state where the precursor is dissolved to the process vessel and to control the concentration of the precursor.

In this embodiment, the precursor can be continuously and stably supplied to the process vessel in a state where the concentration of the precursor in the medium in the supercritical state is substantially constant. Because of this, in a case where deposition is continuously performed on plural substrates, the deposition method of this embodiment is especially effective.

In the deposition method of this embodiment, it is possible to form various kinds of films on the substrate by using various precursors. For example, Cu film, Ta film, TaN film, Ti film, TiN film and a laminated film thereof can be formed.

Cu(hfac)₂, Cu(acac)₂, Cu(dpm)₂, Cu(dibm)₂, Cu(ibpm)₂, Cu(hfac)TMVS, Cu(hfac)COD, or the like can be used as the precursor for deposition of Cu film.

In this case, hfac represents hexafluoroacetylacetonato, dpm represents dipivaloylmethanato, dibm represents diisobutyrylmethanato, ibpm represents isobutyrylpivaloylmethanato, acac represents acetylacetonato, TMVS represents trimethylvinylsilane, and COD represents 1,5-cyclooctadiene.

Conventionally, it is difficult to continuously and stably supply Cu(hfac)₂, Cu(acac)₂, Cu(dpm)₂, Cu(dibm)₂, and Cu(ibpm)₂, which are solids at normal temperature. Hence, the deposition method of this embodiment is especially effective.

In addition, not only CO₂ but also NH₃ can be used as the medium used in the supercritical state. In a case where NH₃ is be used as the medium used in the supercritical state, it is possible to easily form a nitride metal film.

As an organic solvent used in this embodiment whereby the precursor is dissolved, various organic media can be selected. For example, alcohol, ether, ketone, ester, aliphatic carbon hydride, aromatic chemical compound, or the like can be used. In addition, it is preferable that the organic solvent used in this embodiment have a reducing function of the precursor.

In a case where the organic solvent dissolving the precursor has the reducing function of the precursor, it is not necessary to add the reducing agent for reducing the precursor such as H₂ gas supplied from the line 18. Particularly, alcohol has a strong reducibility.

Furthermore, there are, for example, methanol, ethanol, 1-propanol, 1-butanol, first grade alcohol such as 2-methylpropanol, second grade alcohol such as 2-propanol or 2-butanol, third grade alcohol such as 2-methyl-2-propanol, in the field of alcohol. Particularly, the first grade alcohol has a stronger reducibility than the second and third alcohol so that a higher effect for reducing the precursor can be obtained.

For example, in the deposition where Cu(hfac)₂ is used as the precursor and H₂ gas is used as the reducing agent, a large amount of H₂ is necessary and therefore it is preferable that the molar ratio of H₂ to Cu(hfac)₂ be approximately 157:1. Similarly, in a case where Cu(hfac)₂ is used as the precursor and ethanol is used as the reducing agent, it is preferable to form, for example, the addition organic solvent wherein 48.7 ml of ethanol is combined with 2 g of Cu(hfac)₂.

The above-discussed deposition apparatus 10 includes a control apparatus S having, for example, a recording medium HD consisting of a hard disk and a computer (CPU, not shown). In the control apparatus-S, the CPU operates the deposition apparatus 10 by a program stored in the storage medium HD. For example, based on the program, the control apparatus 10 makes the deposition apparatus 10 perform operations of deposition process such as opening the valve so that the medium in the supercritical state is supplied to the process vessel, or the medium inside of the process vessel is discharged.

Meanwhile, a program for deposition recording in the recording medium may be called a recipe. Operations for deposition by the deposition apparatus discussed in this specification are done by the control apparatus S based on the program (recipe) stored in the storage medium HD.

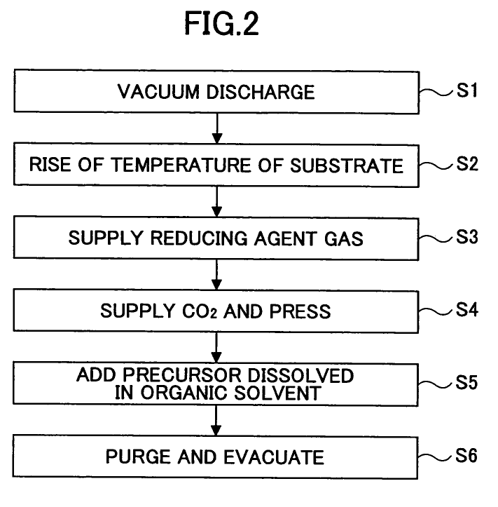

Next, a specific method, by using the above-discussed deposition apparatus 10, for forming a Cu film on the substrate is discussed with reference to FIG. 2. FIG. 2 is a flowchart showing the deposition method according to the first embodiment of the present invention.

Referring to FIG. 2, as the process is started at step 1, the substrate is conveyed into the process space 11A via a gate valve (not shown in FIG. 1) provided at the process vessel so as to be held on the support table 12. Here, the process space 11A is evacuated via the line 17.

Next, at step 2, the substrate is heated by heating means provided in the support table 12 such as a heater so as to have a temperature of 300° C.

Next, at step 3, a reducing agent for reducing the precursor such as H₂ gas is, if necessary, supplied from the line 18 into the process vessel 11. The reducing agent may be supplied together with CO₂. In this case, if the organic solvent where the precursor supplied in the following process is dissolved has good reducibility, this process is not necessary.

Next, at step 4, CO₂ is introduced from the line 15 to the process space 11A so that pressure in the process space 11A is increased. In this case, CO₂ being in the supercritical state in advance may be introduced.

In addition, for example, liquid-state CO₂ may be continuously supplied to the process vessel 11, so that the pressure or temperature of supplied CO₂ may be increased and therefore CO₂ may be in the supercritical state in the process space 11A. In this case, the pressure of the process space 11A may be, for example, 15 MPa.

Next, at step 5, the addition organic solvent which is an organic solvent where the precursor is dissolved is supplied from the line 16 to the process space 11A. In this case, for example, Cu(hfac)₂ is used as the precursor and ethanol is used as the organic solvent. The precursor is added to the medium in the supercritical state supplied to the process space at step 4 so that the precursor is dissolved in the medium in the supercritical state and the process medium is formed and therefore the process medium is supplied on the substrate.

At step 5, the precursor is pyrolytically decomposed on the substrate heated at 300° C., so that a Cu film is deposited on the substrate. In this case, the organic solvent acts as the reducing agent. In a case where the organic solvent does not have a reducibility or the reducibility is not sufficient, for example, H₂ gas which is a reducing agent supplied from the line 18 contributes a decomposition of the precursor.

The medium in the supercritical state and under this pressure, such as CO₂, provides high dissolution of the precursor used for deposition. In addition, the process medium where the precursor is dissolved has high diffusion. Hence, it is possible to implement deposition to a minute pattern at high deposition rate and with a good coverage ratio.

For example, it is possible to form a Cu film at a high deposition rate and with a good filling property without forming a space such as void at a minute pattern having a line width equal to or less than 0.1 μm and formed by an insulation film.

After deposition is performed for a designated time, at step 6, supply of the process medium is stopped and the valves 19A and 19C are opened, so that the process medium in the process space 11A is discharged from the discharge line 19. In this case, the pressure of the discharged medium is controlled by the pressure adjusting valve 19B so as to be prevented from being too high. In this case, if necessary, the process space 11A is purged by supplying CO₂ from the line 15 to the process space 11A.

After the purging is completed, the pressure of the process space 11A is returned to atmospheric pressure so that the deposition is completed.

In a case where the deposition is continuously, implemented for plural substrates after this, the substrate is discharged from the process vessel 11 and then the processes of step 1 through step 6 are repeated. In this case, according to the deposition method of this embodiment, it is possible to stably and continuously supply the process medium wherein the concentration of the precursor dissolved in the medium in the supercritical state is substantially constant in the deposition for plural substrates.

### Second Embodiment

In the deposition apparatus 10 shown in FIG. 1, in a case where the reducing agent is supplied to the process vessel, for example, it may be difficult to continuously supply the reducing agent to the medium in the supercritical state at good reproducibility and a stable mixing ratio. For example, in a case where the reducing agent is supplied from the line 18 to the process vessel, it may be difficult to make a proper mixing ratio of the medium in the supercritical state or the precursor. Hence, it may be difficult to secure controllability for controlling the mixing ratio.

Furthermore, H₂ gas as the reducing agent is explosive at a concentration greater than the explosion limitation. Hence, it is difficult to directly mix H₂ having a low pressure with CO₂ having a high pressure.

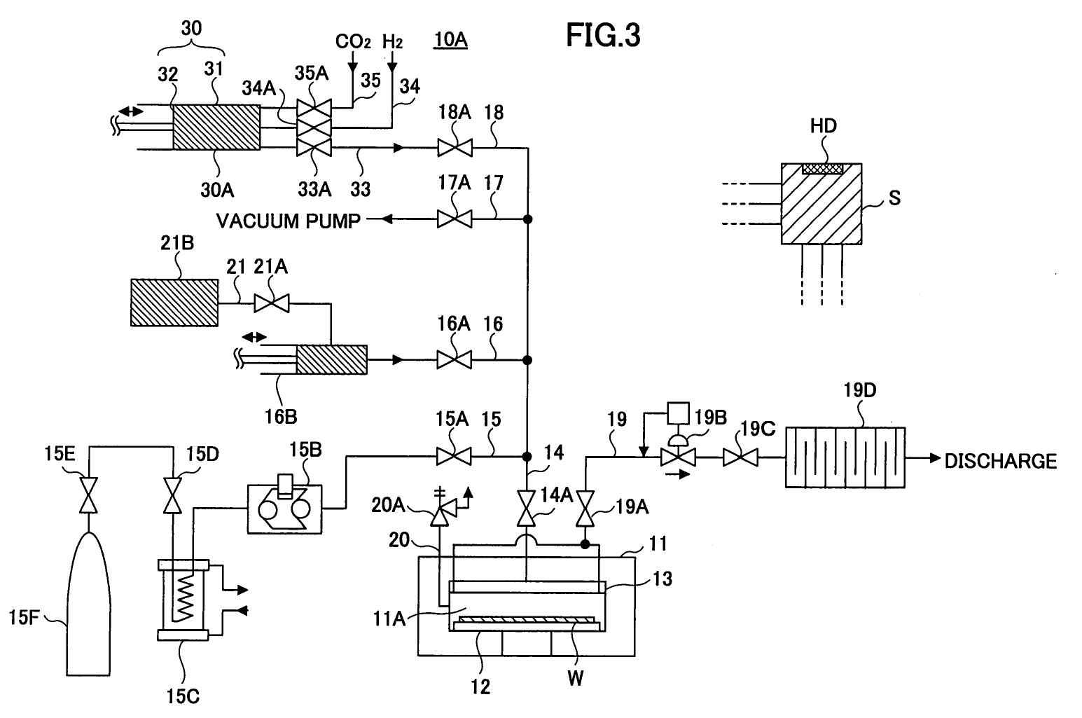

In the present invention, the deposition apparatus 10 shown in FIG. 1 can be modified to be a deposition apparatus 10A shown in FIG. 3. Here, FIG. 3 is a schematic view of an example of the deposition apparatus 10A used for a deposition method of a second embodiment of the present invention. In FIG. 3, parts that are the same as the parts shown in FIG. 1 are given the same reference numerals, and explanation thereof is omitted.

In the deposition apparatus 10A of this embodiment, a mixing vessel 30 for mixing the reducing agent and a dilution medium diluting the reducing agent is connected to the line 18.

The mixing vessel 30 consists of, for example, a cylinder pump. The mixing vessel 30 includes an outside vessel 31 having a substantially cylindrical-shaped configuration and a pressing part 32 inserted in the outside vessel 31 and having a piston-shaped configuration.

A reducing agent and a dilution medium are supplied to a mixing area formed by the outside vessel 31 and the pressing part 32 so as to be mixed. The volume of the mixing area 30A can be changed by operating the pressing part 32 so that the pressure of the mixing area can be controlled. A line 33 having a valve 33A and a line 35 having a valve 35A are connected to the outside vessel 31.

By opening these valves, the reducing agent such as H₂ gas is supplied from the line 34 to the mixing area 30A, the dilution medium such as CO₂ is supplied from the line 35 to the mixing area 30A, and a mixed medium formed by mixing the reducing agent and the dilution medium in the mixing area 30A is supplied from the line 33 to the process space 11A via the line 18.

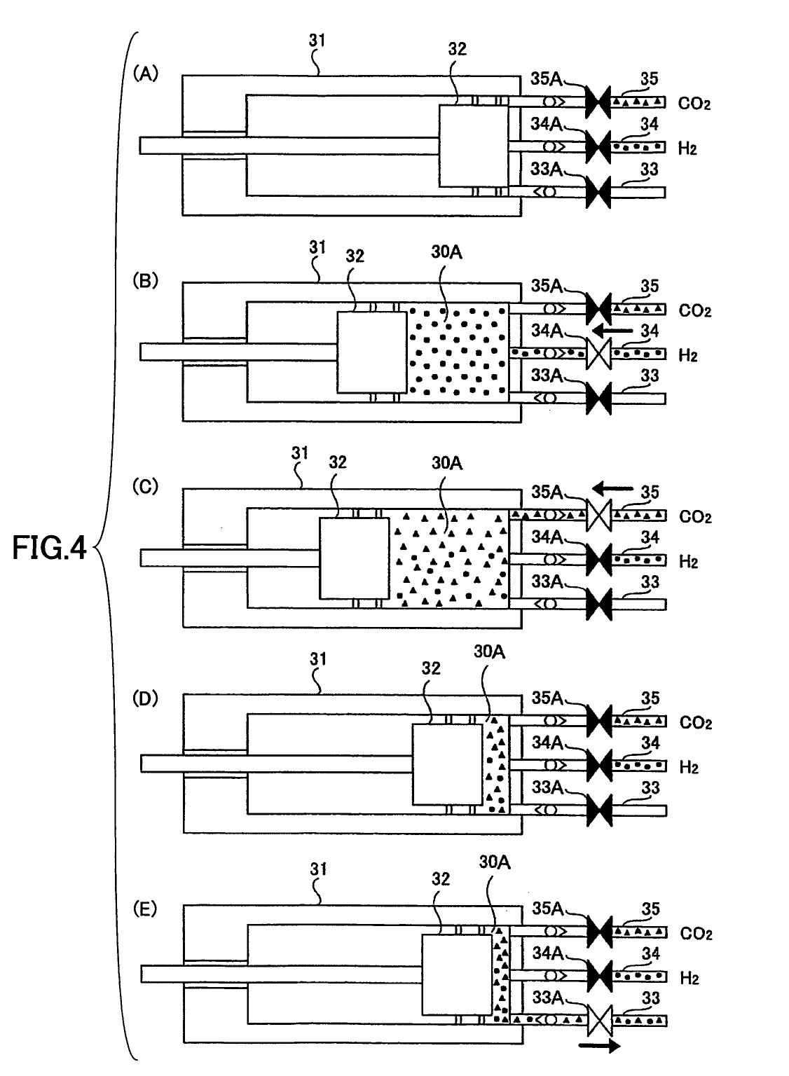

Next, an example of a method for supplying the mixed medium to the process space 11A by using the mixing vessel 30 is discussed with reference to FIG. 4-(A) through FIG. 4-(E).

Here, FIG. 4-(A) through FIG. 4-(E) provides a schematic view showing details of steps for supplying the mixed medium to the process space 11A by using the mixing vessel 30. In FIG. 4, parts that are the same as the parts shown in FIG. 1 through FIG. 3 are given the same reference numerals, and explanation thereof is omitted.

First, in the process shown in FIG. 4-(A), the mixing area 30A is made smallest by the pressing part 32.

Next, in the process shown in FIG. 4-(B), the valve 34A is opened so that H₂ gas as the reducing agent is supplied from the line 34 to the mixing vessel 30 and the pressing part 32 is moved, and thereby the mixing area 30A is formed. In this case, a force moving the pressing part 32 is exerted by the pressure of the reducing agent. Another force may be actively added to the pressing part 32 so that the reducing agent can be taken in by suction.

After a designated amount of the reducing agent is supplied, the valve 34A is closed. In this process, the volume of the mixing area 30A is made to be 3.3 l and the partial pressure of H₂ gas in the mixing area 30A, which becomes substantially the same as the total pressure of the mixing area in this process, is made to be 0.3 MPa. About 0.38 mol of H₂ is held in the mixing area 30A.

Next, in the process shown in FIG. 4-(C), the valve 35A is opened so that CO₂ gas as the dilution medium is supplied from the line 35 to the mixing vessel 30 and the mixing medium made of the reducing agent and the dilution medium is formed; thereby the pressing part 32 is moved and the mixing area 30 A is made larger. In this case, a force moving the pressing part 32 is exerted by the pressure of the reducing agent. Another force may be actively added to the pressing part 32 so that the dilution medium can be taken in by suction.

After a designate amount of the dilution medium is supplied, the valve 35A is closed. In this process, the volume of the mixing area 30A is made to be 5.2 l, the partial pressure of H₂ gas in the mixing area 30A is made to be 0.19 MPa, and the partial pressure of CO₂ gas in the mixing area 30A is made to be 6 MPa. About 0.38 mol of H₂ and 17.6 mol of CO₂ are held in the mixing area 30A. In this process, H₂ gas is diluted so as to have a concentration less than the explosion limitation.

Next, in the process shown in FIG. 4-(D), the pressing part 32 is operated to compress the mixed medium so that the mixing area 30A is made small. In this process, the total pressure of the mixing area 30A is made to be 14.6 MPa (the partial pressure of H₂ is made to be 0.99 MPa). In addition, the temperature of the mixing vessel is 40° C. and the temperature of the mixed medium is 40° C. Hence, in this step, CO₂ in the mixing area 30A becomes the medium in the supercritical state.

Next, in the process shown in FIG. 4-(E), the valve 33A is opened so that a mixed medium made of CO₂ in the supercritical state and H₂ is supplied to the process space 11A via the line 33, the line 18, and the line 14.

The reducing agent supplied to the process vessel is supplied to the substrate in the process vessel 11 by the deposition method shown in FIG. 2 of the first embodiment, for example, so that the reducing agent is mixed with CO₂ in the supercritical state or the precursor. As a result of this, the reducing agent acts as a reducing agent of the precursor so as to contribute to deposition.

In the deposition method of this embodiment, it is possible to continuously and stably supply the reducing agent, such as H₂, reducing the precursor on the substrate in the process vessel. Particularly, process efficiency is improved in a case where the deposition is continuously performed on the substrates. In this case, for example, it is possible to continuously supply a designated amount of the mixed medium having a designated concentration to the processed vessel by repeating the processes shown FIG. 4-(A) through FIG. 4-(E).

In addition, since explosive gas such as H₂ gas is diluted by a dilution medium so as to be below the explosion limitation and then supplied to the process vessel, the probability of explosion of the reducing agent becomes low and therefore it is possible to supply the reducing agent safely.

Furthermore, since the reducing agent is diluted in the mixing vessel 30 so as to have a desirable concentration, it is possible to improve controllability of the amount or concentration of the reducing agent supplied on the substrate.

In addition, in this case, if the dilution medium diluting the reducing agent is the same medium as the medium in the supercritical state supplied to the process vessel, namely the medium where the precursor is dissolved, the critical point is the same. Hence, for example, it is preferable to use CO₂.

### Third Embodiment

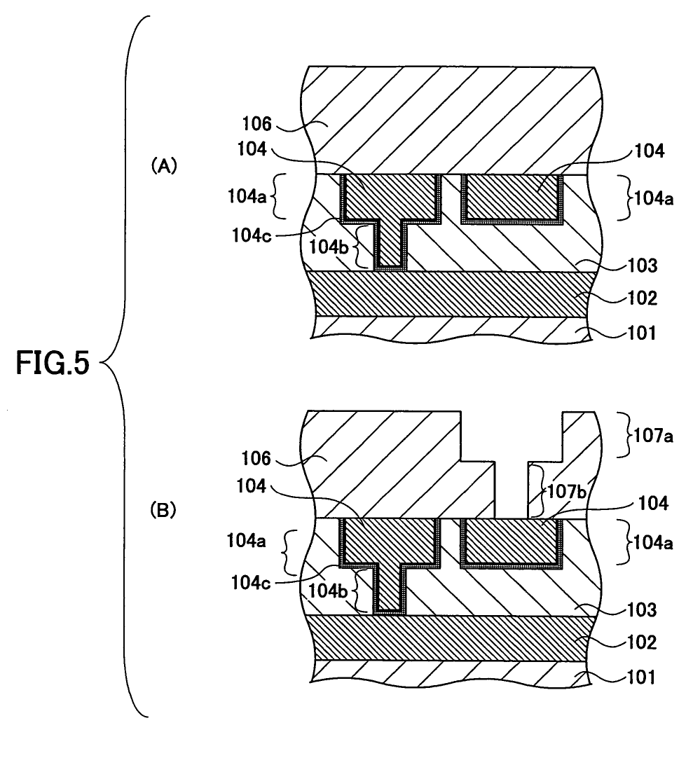

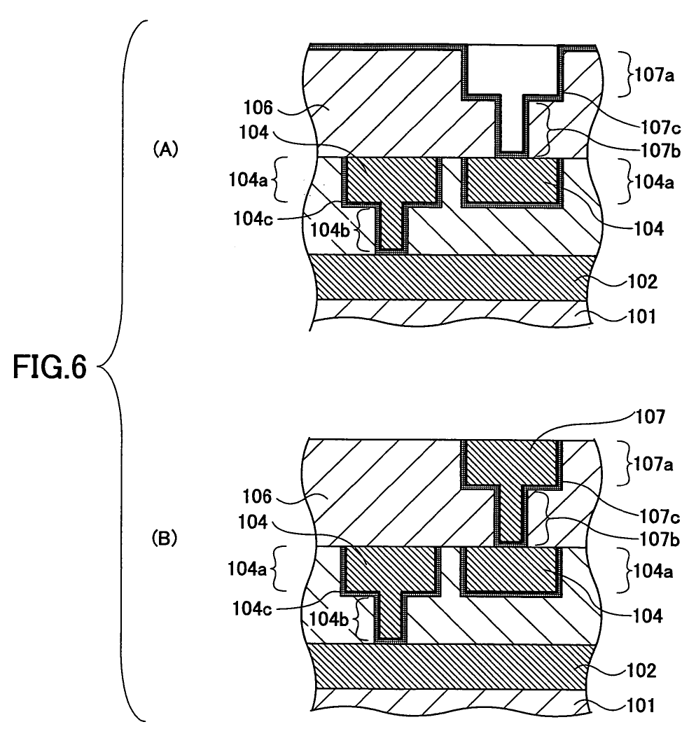

Next, an example for forming a semiconductor device using the method discussed in the first or second embodiment is shown in FIG. 5 and FIG. 6.

FIG. 5-(A), FIG. 5-(B), FIG. 6-(C), and FIG. 6-(D) show manufacturing steps of a semiconductor device using the method discussed in the first and second embodiments of the present invention.

Referring to FIG. 5-(A), an insulation film such as a silicon oxide film 101 is formed so as to cover an element such as a MOS transistor formed on a semiconductor substrate made of silicon. Furthermore, a wiring layer (not shown in FIG. 5) made of W, for example, electrically connected to the element and a wiring layer 102 made of Cu, for example, connected to the wiring layer are formed.

A first insulation layer 103 is formed on the silicon oxide film 101 so as to cover the wiring film 102. A groove forming part 104a and a hole forming part 104b are formed in the first insulation layer 103. A wiring layer 104 formed by Cu and consisting of trench wiring and via wiring is formed in the groove forming part 104a and the hole forming part 104b and the via wiring is electrically connected to the wiring layer 102.

A barrier layer 104c is formed between the first insulation layer 103 and the wiring layer 104. The barrier layer 104c prevents Cu from diffusing from the wiring layer 104 to the first insulation layer 103. In addition, a second insulation layer 106 is formed so as to cover upper parts of the wiring layer 104 and the first insulation layer 103. In this embodiment, a method for forming a Cu film by applying the deposition method of the present invention to the second insulation layer 106 is employed. The wiring layer 104 may be formed by using the method discussed in the first or second embodiment.

In the process shown in FIG. 5-(B), the groove forming part 107a and a hole forming part 107b are formed in the second insulation layer 106 by a dry etching method, for example.

Next, in a process shown in FIG. 6-(C), a barrier layer 107c which prevents Cu from diffusing is deposited on the second insulation layer 106 including internal wall surfaces of the groove forming part 107a and the hole forming part 107b and the exposed surface of wiring layer 104.

The barrier layer 107c is, for example, made of a laminated film of a Ta film and a TaN film in this case, and may be formed by a sputtering method. As discussed in the first embodiment, the barrier layer 107c can be formed by using the deposition apparatus 10 and a method for supplying a process medium wherein the precursor is dissolved in the medium in the supercritical state. In this case, it is possible to form the barrier layer 107c for preventing the diffusion of Cu at a minute pattern at a good coverage ratio.

In this case, for example, TaF₅, TaCl₅, TaBr₅, TaI₅, (C₅H₅)₂TaH₃, (C₅H₅)₂TaCl₃, PDMAT (Pentakis (dimethylamino) Tantalum), [(CH₃)₂N]₅Ta)), PDEAT (Pentakis(diethylamino)Tantalum), [(C₂H₅)₂N]₅Ta)), TBTDET (Ta(NC(CH₃)₃(N(C₂H₅)₂)₃), or TAIMATA (registered trademark, Ta(NC(CH₃)₂C₂H₅)(N(CH₃)₂)₃)) may be used as the precursor. CO₂ or NH₃ is used as the medium in the supercritical state so that the barrier layer 107c made of Ta/TaN is formed. Such a barrier layer may be formed by using so called ALD method.

Next, as shown in FIG. 6-(D), by using a method discussed in the first or second embodiment, the wiring layer 107 made of Cu is formed on the barrier layer 107c including the groove forming part 107a and the hole forming part 107b. In this case, as described above, since CO₂ in the supercritical state is used and CO₂ in the supercritical state where a Cu deposition precursor is dissolved has good diffusion, it is possible to form the wiring layer 107 on the fine hole forming part 107b and the bottom part and the side wall part of the grove forming part 107a with good coverage.

Furthermore, after this process, it is possible to form a 2+n (n: natural number)th insulation layer on an upper part of the second insulation layer 106 and form the wiring film made of Cu on each of the insulation layers by using the deposition method of the present invention.

In addition, in this embodiment, while the laminated film of the Ta film and the TaN film is used as the barrier layer, the present invention is not limited to this example. Various kinds of barrier film can be used. For example, a WN film, a W film, and a laminated film formed by Ti film and TiN film can be used as the barrier layer.

Furthermore, various kinds of material can be used for the first insulation layer 103 or the second insulation layer 106. For example, SiO₂ film (silicon oxide film), SiOF film (fluoridation silicon oxide film), SiCO(H) film, or the like can be used for the first insulation layer 103 or the second insulation layer 106.

Thus, according to the above-discussed embodiments, a deposition method for depositing on a substrate, including the step of using a process medium made by adding a precursor to a medium in a supercritical state; wherein the precursor is added to the medium in the supercritical state where the precursor is dissolved in an organic solvent, is provided.

The medium in the supercritical state may be supplied on the substrate; and the organic solvent wherein the precursor may be dissolved is added to the medium in the supercritical state. The organic solvent may have a reducing property. The organic solvent may includes alcohol. The alcohol includes at least one of methanol, ethanol, 1-propanol, 1-butanol, and 2-methylpropanol. The precursor includes Cu. The precursor may be selected from a group consisting of Cu(hfac)₂, Cu(acac)₂, Cu(dpm)₂, Cu(dibm)₂ and Cu(ibpm)₂. The medium in the supercritical state includes CO₂.

Thus, according to the above-discussed embodiments, a deposition method wherein a precursor, a medium in a supercritical state dissolving the precursor, and a reducing agent reducing the precursor are supplied on a substrate held in a process vessel so that deposition is implemented, the deposition method including the steps of:

a first step of supplying the reducing agent to a mixing vessel mixing the reducing agent and a dilution agent of the reducing agent;

a second step of supplying the dilution agent to the mixing vessel so as to dilute the reducing agent and form a mixed medium;

a third step of compressing the mixed medium; and

a fourth step of supplying the mixed medium into the process vessel, is also provided.

The reducing agent may include H₂ gas. The H₂ gas in the mixing vessel may be diluted in the second step so as to have a density equal to or less than an explosive limit density of the H₂ gas. The dilution agent and the medium in the supercritical state may be made of a same medium. The dilution agent may include CO₂. The medium in the supercritical state may include CO₂. The mixing vessel may be made of a cylinder pump. The dilution medium may be in the supercritical state in the fourth step. The deposition method may further include a step of continuously supplying the mixed medium into the process vessel by repeating the first through fourth steps.

Thus, according to the above-discussed embodiments, a deposition method wherein a precursor, a medium in a supercritical state dissolving the precursor, and a reducing agent reducing the precursor are supplied on a substrate held in a process vessel so that deposition is implemented; and the precursor is added to the medium in the supercritical state where the precursor is dissolved in an organic solvent; the deposition method including:

a first step of supplying the reducing agent to a mixing vessel mixing the reducing agent and a dilution agent of the reducing agent;

a second step of supplying the dilution agent to the mixing vessel so as to dilute the reducing agent and form a mixed medium;

a third step of compressing the mixed medium; and

a fourth step of supplying the mixed medium into the process vessel, is also provided.

The dilution agent and the medium in the supercritical state may include CO₂. The reducing agent may include H₂ gas.

Thus, according to the above-discussed embodiments, a recording medium wherein a program making a computer implement a deposition method is recorded, the deposition method being wherein a precursor, a medium in a supercritical state dissolving the precursor, and a reducing agent reducing the precursor are supplied on a substrate held in a process vessel so that deposition is implemented, the deposition method including:

a first step of supplying the reducing agent to a mixing vessel mixing the reducing agent and a dilution agent of the reducing agent;

a second step of supplying the dilution agent to the mixing vessel so as to dilute the reducing agent and form a mixed medium;

a third step of compressing the mixed medium; and

a fourth step of supplying the mixed medium into the process vessel, is also provided.

Thus, according to the above-discussed embodiments, a recording medium wherein a program making a computer implement a deposition method is recorded, the deposition method being wherein a precursor, a medium in a supercritical state dissolving the precursor, and a reducing agent reducing the precursor are supplied on a substrate held in a process vessel so that deposition is implemented; and the precursor is added to the medium in the supercritical state where the precursor is dissolved in an organic solvent; the deposition method including:

a first step of supplying the reducing agent to a mixing vessel mixing the reducing agent and a dilution agent of the reducing agent;

a second step of supplying the dilution agent to the mixing vessel so as to dilute the reducing agent and form a mixed agent;

a third step of compressing the mixed medium; and

a fourth step of supplying the mixed medium into the process vessel, is also provided.

According to the above-discussed embodiments, a deposition method using a medium in a supercritical state whereby a material is stably supplied on a substrate is provided.

The present invention is not limited to these embodiments, but variations and modifications may be made without departing from the scope of the present invention.

This patent application is based on Japanese Priority Patent Application No. 2004-304537 filed on Oct. 19, 2004, the entire contents of which are hereby incorporated by reference.

What is claimed is:

1. A deposition method for depositing on a substrate, comprising the step of:
using a process medium made by adding a precursor to a medium in a supercritical state;
wherein the precursor is added to the medium in the supercritical state where the precursor is dissolved in an organic solvent.

2. The deposition method as claimed in claim 1,
wherein the medium in the supercritical state is supplied on the substrate; and
the organic solvent wherein the precursor is dissolved is added to the medium in the supercritical state.

3. The deposition method as claimed in claim 1,
wherein the organic solvent has a reducing property.

4. The deposition method as claimed in claim 1,
wherein the organic solvent includes alcohol.

5. The deposition method as claimed in claim 4,
wherein the alcohol includes at least one of methanol, ethanol, 1-propanol, 1-butanol, and 2-methylpropanol.

6. The deposition method as claimed in claim 1,
wherein the precursor includes Cu.

7. The deposition method as claimed in claim 6,
wherein the precursor is selected from a group consisting of Cu(hfac)₂, Cu(acac)₂, Cu(dpm)₂, Cu(dibm)₂ and Cu(ibpm)₂.

8. The deposition method as claimed in claim 6,
wherein the medium in the supercritical state includes CO₂.

9. A deposition method wherein a precursor, a medium in a supercritical state dissolving the precursor, and a reducing agent reducing the precursor are supplied on a substrate held in a process vessel so that deposition is implemented, the deposition method comprising the steps of:
a first step of supplying the reducing agent to a mixing vessel mixing the reducing agent and a dilution agent of the reducing agent;
a second step of supplying the dilution agent to the mixing vessel so as to dilute the reducing agent and form a mixed medium;
a third step of compressing the mixed medium; and
a fourth step of supplying the mixed medium into the process vessel.

10. The deposition method as claimed in claim 9,
wherein the reducing agent includes H₂ gas.

11. The deposition method as claimed in claim 10,
wherein the H₂ gas in the mixing vessel is diluted in the second step so as to have a density equal to or less than an explosive limit density of the H₂ gas.

12. The deposition method as claimed in claim 9,
wherein the dilution agent and the medium in the supercritical state are made of a same medium.

13. The deposition method as claimed in claim 9,
wherein the dilution agent includes CO₂.

14. The deposition method as claimed in claim 9,
wherein the medium in the supercritical state includes CO₂.

15. The deposition method as claimed in claim 9,
wherein the mixing vessel is made of a cylinder pump.

16. The deposition method as claimed in claim 9,
wherein the dilution medium is in the supercritical state in the fourth step.

17. The deposition method as claimed in claim 9, further comprising:
a step of continuously supplying the mixed medium into the process vessel by repeating the first through fourth steps.

18. A deposition method wherein a precursor, a medium in a supercritical state dissolving the precursor, and a reducing agent reducing the precursor are supplied on a substrate held in a process vessel so that deposition is implemented; and the precursor is added to the medium in the supercritical state where the precursor is dissolved in an organic solvent; the deposition method comprising:
a first step of supplying the reducing agent to a mixing vessel mixing the reducing agent and a dilution agent of the reducing agent;
a second step of supplying the dilution agent to the mixing vessel so as to dilute the reducing agent and form a mixed medium;
a third step of compressing the mixed medium; and
a fourth step of supplying the mixed medium into the process vessel.

19. The deposition method as claimed in claim 18,
wherein the dilution agent and the medium in the supercritical state include CO₂.

20. The deposition method as claimed in claim 18,
wherein the reducing agent includes H₂ gas.

21. A recording medium wherein a program making a computer implement a deposition method is recorded, the deposition method being wherein a precursor, a medium in a supercritical state dissolving the precursor, and a reducing agent reducing the precursor are supplied on a substrate held in a process vessel so that deposition is implemented, the deposition method comprising:
a first step of supplying the reducing agent to a mixing vessel mixing the reducing agent and a dilution agent of the reducing agent;
a second step of supplying the dilution agent to the mixing vessel so as to dilute the reducing agent and form a mixed medium;
a third step of compressing the mixed medium; and
a fourth step of supplying the mixed medium into the process vessel.

22. A recording medium wherein a program making a computer implement a deposition method is recorded, the deposition method being wherein a precursor, a medium in a supercritical state dissolving the precursor, and a reducing agent reducing the precursor are supplied on a substrate held in a process vessel so that deposition is implemented; and the precursor is added to the medium in the supercritical state where the precursor is dissolved in an organic solvent; the deposition method comprising:
a first step of supplying the reducing agent to a mixing vessel mixing the reducing agent and a dilution agent of the reducing agent;
a second step of supplying the dilution agent to the mixing vessel so as to dilute the reducing agent and form a mixed agent;
a third step of compressing the mixed medium; and
a fourth step of supplying the mixed medium into the process vessel.
